(19) United States
(12) Patent Application Publication
(10) Pub. No.: US 2026/0239909 A1
(43) Pub. Date: Aug. 13, 2026

(54) METHOD FOR SURFACE TREATMENT OF LIGHT-EMITTING ELEMENT, METHOD OF MANUFACTURING DISPLAY DEVICE COMPRISING LIGHT-EMITTING ELEMENT PROVIDED USING INK, AND ELECTRONIC DEVICE COMPRISING DISPLAY DEVICE

(71) Applicant: Samsung Display Co., Ltd., Yongin-si (KR)

(72) Inventor: Jue Youn PARK, Yongin-si (KR)

(21) Appl. No.: 19/296,123

(22) Filed: Aug. 11, 2025

(30) Foreign Application Priority Data
Feb. 10, 2025 (KR) 10-2025-0016580

(51) Int. Cl. H01L 21/02; H01L 21/324; H10H 20/01

(52) U.S. Cl. CPC H10P 70/20; H10H 20/013; H10P 95/904

(57) ABSTRACT

A method for surface treatment of a light-emitting element, a method of manufacturing a display device including a light-emitting element provided using ink, and an electronic device including the display device are provided. The method for surface treatment includes performing ultraviolet ozone (UVO) treatment on a target layer, and forming a self-assembled layer on the target layer. The performing the UVO treatment may include irradiating the target layer with UV light for about 50 minutes to about 70 minutes. The forming the self-assembled layer may include dipping the target layer into a mixing solution including ethanol and a coupling agent at about 50° C. to about 70° C.

### CROSS-REFERENCE TO RELATED APPLICATION

The present application claims priority to and the benefits of Korean Patent Application Number 10-2025-0016580, filed on Feb. 10, 2025, in the Korean Intellectual Property Office, the entire content of which is incorporated herein by reference.

### BACKGROUND

### 1. Field

One or more embodiments of the present disclosure relate to a method for surface treatment of a light-emitting element, a method of manufacturing a display device including a light-emitting element provided using ink, and an electronic device including such a display device.

### 2. Description of the Related Art

With the rapid advancement of information technology, there has been significant research and development in display devices for various information displays applications.

As a light source for a display device, a variety of self-emissive elements may be utilized and provided on a substrate by one or more suitable process methods. For example, self-emissive light elements may be aligned on a substrate by an inkjet process. In order to properly provide the light-emitting elements to the substrate using ink, it may be desirable for the light-emitting elements to have properties that allow the light-emitting elements to be stably dispersed in the ink (e.g., it is desirable that the light-emitting elements exhibit properties that enable stable dispersion within an ink).

### SUMMARY

One or more aspects of embodiments of the present disclosure are directed toward a method for surface treatment of a light-emitting element, a method of manufacturing a display device including a light-emitting element provided with ink, and an electronic device including the display device, in each of which a plurality of reactive functional groups (e.g., hydroxyl groups) may be formed by appropriately or suitably performing surface treatment of a target layer to thereby form a dense self-assembled layer.

One or more aspects of embodiments of the present disclosure are directed toward a method for treating a surface of a light-emitting element, a method of manufacturing a display device including a light-emitting element provided using ink, and an electronic device including the display device, in each of which dispersion characteristics among light-emitting elements are improved by forming a dense self-assembled layer and thus the light-emitting elements may be efficiently aligned.

One or more aspects of embodiments of the present disclosure are directed toward a method for treating a surface of a light-emitting element, a method of manufacturing a display device including a light-emitting element provided using ink, and an electronic device including the display device, in each of which contaminants from a target layer may be effectively removed.

Additional aspects will be set forth in part in the description which follows and, in part, will be apparent from the description, or may be learned by practice of the presented embodiments.

According to one or more embodiments of the present disclosure, a method for surface treatment may include performing an ultraviolet ozone (UVO) treatment on a target layer, and forming a self-assembled layer on the target layer. The performing the UVO treatment may include irradiating the target layer with UV light for about 50 minutes to about 70 minutes. The forming the self-assembled layer may include dipping (e.g., immersing) the target layer into a mixing solution including ethanol and a coupling agent at about 50° C. to about 70° C.

In one or more embodiments, in the forming of the self-assembled layer, the coupling agent may be contained at a concentration of about 50 millimolar (mM) to about 100 millimolar (mM) in the mixing solution.

In one or more embodiments, in the forming of the self-assembled layer, a container receiving the mixing solution may include a plastic material.

In one or more embodiments, the UV light may have a wavelength of about 184 nm to about 324 nm.

In one or more embodiments, the performing the UVO treatment may be carried out within a temperature of about 20° C. to about 40° C.

In one or more embodiments, in the irradiating of the target layer, the UV light may be provided while water is arranged around the target layer.

In one or more embodiments, an amount of the water provided on the target layer may be from about 1 mL to about 10 mL per unit area (1 cm²) of the target layer.

In one or more embodiments, the coupling agent may be hexyltrimethoxysilane.

In one or more embodiments, the dipping the target layer may be performed for a period from about 17 hours to about 48 hours.

In one or more embodiments, the method for surface treatment may further include pre-cleaning the target layer before performing the UVO treatment The pre-cleaning the target layer may include ultrasonically cleaning the target layer using (e.g., with) a pre-cleaning mixing solution including ethanol and water.

In one or more embodiments, the method for surface treatment may further include performing a heat treatment process after forming the self-assembled layer. The performing the heat treatment process may include performing a bake process at a temperature range of about 100° C. to about 140° C. for a period of about 0.5 hours to about 1.5 hours.

In one or more embodiments, the method for surface treatment may further include post-cleaning the target layer after performing the heat treatment process. The post-cleaning the target layer may include ultrasonically cleaning the target layer using (e.g., with) an organic solvent; and drying the target layer using nitrogen gas.

According to one or more embodiments of the present disclosure, a method of manufacturing a display device may include providing an ink including a light-emitting element and a solvent on a base layer, aligning the light-emitting element between a first electrode and a second electrode formed on the base layer, and forming a first connection electrode electrically connected to a first end of the light-emitting element and a second connection electrode electrically connected to a second end of the light-emitting element. The light-emitting element may include a semiconductor layer and a cover layer covering at least a portion of the semiconductor layer. The cover layer may be surface-treated by the method for surface treatment and includes a cover base forming the target layer and the self-assembled layer formed on the cover base.

According to one or more embodiments of the present disclosure, an electronic device may include a processor, the display device manufactured according to the manufacturing method and outputting image information based on a signal provided from the processor, and a power module supplying power to the display device.

For example, the methods and structures described herein enable improved integration of light-emitting elements into display devices by enhancing surface compatibility, alignment precision, and electrical connectivity. The surface treatment techniques, including ultraviolet ozone (UVO) exposure and self-assembled layer formation, contribute to improved ink dispersion stability, reduced contamination, and enhanced bonding characteristics.

### BRIEF DESCRIPTION OF THE DRAWINGS

The accompanying drawings are included to provide a further understanding of the present disclosure and are incorporated in and constitute a part of this disclosure. The drawings illustrate example embodiments of the disclosure and, together with the description, serve to explain principles of the present disclosure. The above and other aspects and features of embodiments according to the present disclosure will become more apparent from the following description of, in further detail, aspects of one or more embodiments thereof with reference to the accompanying drawings, in which:

FIG. 1 is a schematic perspective view of a light-emitting element according to one or more embodiments of the present disclosure;

FIG. 2 is a schematic cross-sectional view of a light-emitting element according to one or more embodiments of the present disclosure;

FIG. 3 is a flowchart illustrating a method for surface treatment of a light-emitting element according to one or more embodiments of the present disclosure;

FIG. 4 is a schematic cross-sectional view illustrating some of manufacturing processes of a method for surface treatment of a light-emitting element according to one or more embodiments of the present disclosure;

FIG. 5 is a graph showing adhesion force test results for manufactured examples of the present disclosure;

FIG. 6 is a schematic plan view illustrating a display device according to one or more embodiments of the present disclosure;

FIG. 7 is a schematic cross-sectional view illustrating a display device according to one or more embodiments of the present disclosure;

FIG. 8 is a flowchart illustrating a method of manufacturing a display device according to one or more embodiments of the present disclosure;

FIG. 9 is a schematic cross-sectional view illustrating some of manufacturing processes of a method of manufacturing a display device according to one or more embodiments of the present disclosure;

FIG. 10 is a diagram illustrating an electronic device according to one or more embodiments of the present disclosure; and

FIG. 11 shows schematic views of various embodiments of an electronic device according to the present disclosure.

### DETAILED DESCRIPTION

Embodiments of the present disclosure may be modified in one or more suitable manners and have one or more suitable forms. Therefore, example embodiments will be illustrated in the drawings and will be described in more detail in the disclosure. However, it should be understood that the present disclosure is not intended to be limited to the disclosed specific forms, and the disclosure includes all modifications, equivalents, and substitutions within the spirit and technical scope of the disclosure.

Terms of “first,” “second,” and/or the like may be used to describe one or more suitable components, but the components should not be limited by such terms. These terms are used only for the purpose of distinguishing one component from another component. For example, without departing from the scope of the disclosure, a first component may be referred to as a second component, and similarly, a second component may also be referred to as a first component. In the following description, the singular expressions include plural expressions unless the context clearly dictates otherwise. For example, the singular forms “a,” “an,” “one,” and “the” are intended to include the plural forms as well, unless the context clearly indicates otherwise. Further, the use of “may” when describing embodiments of the present disclosure refers to “one or more embodiments of the present disclosure.

It should be understood that in the present disclosure, terms such as “comprise(s)/comprising” “include(s)/including”, “has(have)/having”, and/or the like are used to specify that there is a feature, a number, a step (e.g., act or task), an operation, a component, a part, or a combination thereof described in the disclosure, but does not exclude a possibility of the presence or addition of one or more other features, numbers, steps, operations, components, parts, or combinations thereof in advance. Additionally, the terms “comprise(s)/comprising,” “include(s)/including,” “have/has/having,” or other similar terms include or support the terms “consisting of” and “consisting essentially of,” indicating the presence of stated features, numbers, steps, operations, elements, and/or components, without or essentially without the presence of other features, numbers, steps, operations, elements, components, and/or groups thereof. Furthermore, in case that a first part such as a layer, a film, a region, or a plate is arranged “on” a second part, the first part may be “directly on” the second part, or a third part may intervene between them. In addition, if (e.g., when) it is expressed that a first part such as a layer, a film, a region, or a plate is formed on a second part, the surface of the second part on which the first part is formed is not necessarily limited to an upper surface of the second part but may include other surfaces such as a side surface or a lower surface of the second part. In contrast, “directly on” may refer to that there are no additional layers, films, regions, plates, and/or the like, between a layer, a film, a region, a plate, and/or the like and the other part. For example, “directly on” may refer to two layers or two members are arranged without utilizing an additional member such as an adhesive member therebetween. In addition, in case that a first part such as a layer, a film, a region, or a plate is “under” a second part, the first part may be “directly under” the second part, or a third part may intervene between them.

One or more embodiments of the present disclosure relate to a method for surface treatment of a light-emitting element, a method of manufacturing a display device including a light-emitting element provided using ink, and an electronic device including the display device. Hereinafter, with reference to the accompanied drawings, a method for surface treatment of a light-emitting element, a method of manufacturing a display device including a light-emitting element provided using ink, and an electronic device including the display device in accordance with one or more embodiments will be described in more detail.

### 1. Light-Emitting Element

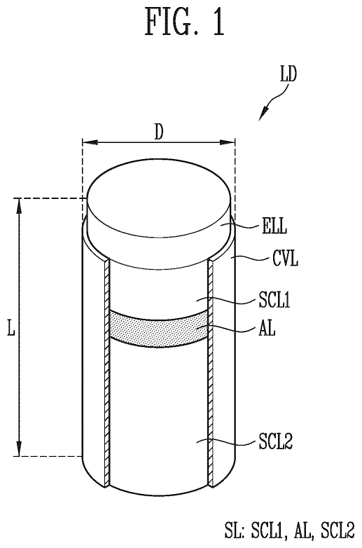

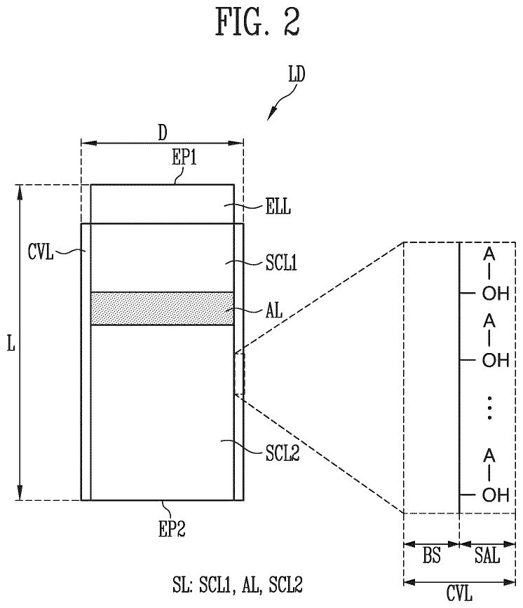

Referring to FIG. 1 and FIG. 2, a light-emitting element LD according to one or more embodiments will be described.

FIG. 1 is a schematic perspective view of the light-emitting element LD according to one or more embodiments. FIG. 2 is a schematic cross-sectional view illustrating the light-emitting element LD according to one or more embodiments.

The light-emitting element LD is configured to emit light. The light-emitting element LD may include a semiconductor layer SL and a cover layer CVL. The light-emitting element LD may further include an electrode layer ELL.

The semiconductor layer SL may include a first semiconductor layer SCL1, a second semiconductor layer SCL2, and an active layer AL between (e.g., arranged between) the first semiconductor layer SCL1 and the second semiconductor layer SCL2. According to one or more embodiments, the first semiconductor layer SCL1, the active layer AL, and the second semiconductor layer SCL2 may be stacked sequentially in a length (L) direction of the light-emitting element LD.

The light-emitting element LD may have one or more suitable shapes. For example, in one or more embodiments, the light-emitting element LD may have a column shape (e.g., in a shape of column) extending in one direction. The column shape may include a rod-like shape or a bar-like shape which is elongated (e.g., with an aspect ratio greater than one) in the length (L) direction, such as a circular column, a polygonal column, and/or the like, and a cross-sectional shape of the column is not particularly limited.

The light-emitting element LD may have a first end EP1 and a second end EP2, for example, the first end EP1 and the second end EP2 may be two opposite ends of the light-emitting element LD in the length direction. According to one or more embodiments, the first semiconductor layer SCL1 may be adjacent to the first end EP1 of the light-emitting element LD, and the second semiconductor layer SCL2 may be adjacent to the second end EP2 of the light-emitting element LD. According to one or more embodiments, the electrode layer ELL may be adjacent to the first end EP1.

The light-emitting element LD may be manufactured by etching sequentially stacked semiconductor layers. The light-emitting element LD may have a nano-scale to micro-scale size. For example, each of a diameter D (or a width) of the light-emitting element LD and the length L of the light-emitting element LD may have a size of nanoscale to micro-scale.

The first semiconductor layer SCL1 may include a first conductivity type (kind) of semiconductor. The first semiconductor layer SCL1 may be arranged on the active layer AL and include a different conductivity type (kind) of semiconductor layer from the second semiconductor layer SCL2. For example, in one or more embodiments, the first semiconductor layer SCL1 may include a P-type (kind) semiconductor layer. For example, the first semiconductor layer SCL1 may include one or more semiconductor materials selected from the group consisting of InAlGaN, GaN, AlGaN, InGaN, AlN, and InN, and may include a P-type (kind) semiconductor layer doped with a first conductivity type (kind) of dopant such as Ga, B, and/or Mg. However, embodiments of the present disclosure are not limited to the above examples. The first semiconductor layer SCL1 may include one or more suitable materials.

The active layer AL may be arranged between the first semiconductor layer SCL1 and the second semiconductor layer SCL2. The active layer AL may include a single-quantum well structure or a multi-quantum well structure. The position of the active layer AL is not limited to a particular example and may vary depending on a type (kind) of the light-emitting element LD.

In one or more embodiments, a clad layer doped with a conductive dopant may be formed on one side and/or the other side of the active layer AL. For example, the clad layer may include one or more selected from among AlGaN and InAlGaN. However, embodiments of the present disclosure are not limited to the foregoing examples.

The second semiconductor layer SCL2 may include a second conductivity type (kind) of semiconductor. The second semiconductor layer SCL2 may be arranged on the active layer AL and include a different conductivity type (kind) of semiconductor layer than the first semiconductor layer SCL1. For example, in one or more embodiments, the second semiconductor layer SCL2 may include an N-type (kind) semiconductor layer. For example, the second semiconductor layer SCL2 may include one or more selected from the group consisting of InAlGaN, GaN, AlGaN, InGaN, AlN, and InN, and may include an N-type (kind) semiconductor layer doped with a second conductive dopant such as Si, Ge, and/or Sn. However, embodiments of the present disclosure are not limited to the example described above. The second semiconductor layer SCL2 may include one or more suitable materials.

If (e.g., when) a threshold voltage or greater is applied across the first end EP1 and the second end EP2 of the light-emitting element LD, electron-hole pairs in the active layer AL may recombine with each other, and the light-emitting element LD may be to emit light. By utilizing this principle to control the light emission of the light-emitting element LD, the light-emitting element LD may be utilized as a light source in one or more suitable devices.

The cover layer CVL may be arranged on one surface (e.g., a side) of the semiconductor layer SL. The cover layer CVL may surround (e.g., be around) an outer surface of the active layer AL, and may further surround a portion of each of the first semiconductor layer SCL1 and the second semiconductor layer SCL2.

The cover layer CVL may expose the first end EP1 and the second end EP2 of the light-emitting element LD, each of which has a different polarity. For example, in one or more embodiments, the cover layer CVL may expose an end of each of the electrode layer ELL and the second semiconductor layer SCL2, which are adjacent to the first end EP1 and the second end EP2 of the light-emitting element LD, respectively. The cover layer CVL may secure electrical stability of the light-emitting element LD and minimize or reduce surface defects of the light-emitting element LD to improve lifetime and efficiency.

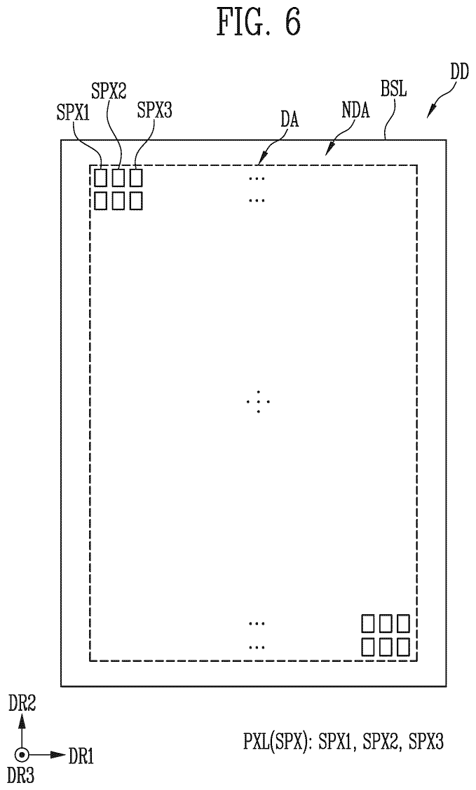

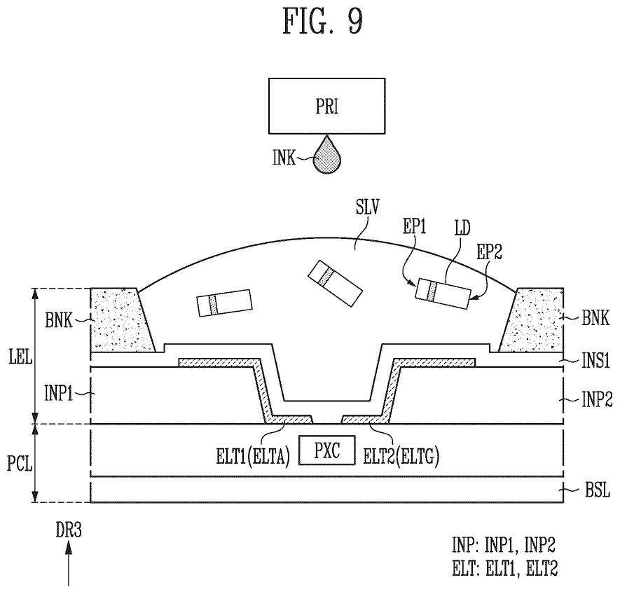

The cover layer CVL may also prevent or reduce the light-emitting elements LD from aggregating when the light-emitting elements LD are supplied to a base layer BSL (see FIG. 6) using an ink INK (see FIG. 9), and may have dispersion characteristics between the light-emitting elements LD.

It may be desirable that the light-emitting elements LD are appropriately or suitably dispersed within the ink INK. For example, the light-emitting elements LD may have a low sedimentation rate within the ink INK, and the light-emitting elements LD may be dispersed and separated from each other for a sufficient amount of time.

When the light-emitting elements LD are properly dispersed in the ink INK, the process efficiency of an inkjet process may be improved, and the light-emitting elements LD may be supplied and evenly distributed among the regions on the base layer BSL. As a result, the light emitting efficiency of a display device DD (see FIG. 6) may be improved.

The cover layer CVL may include two or more layers so that the cover layer CVL may have improved dispersion properties and a low sedimentation rate. For example, in one or more embodiments, the cover layer CVL may include a cover base BS and a self-assembled layer SAL.

The cover base BS may be arranged (e.g., directly arranged) on the semiconductor layer SL and between the semiconductor layer SL and the self-assembled layer SAL. The cover base BS may cover a side surface of the semiconductor layer SL.

The self-assembled layer SAL may be the outermost layer of the light-emitting element LD. In one or more embodiments, a (e.g., one) surface of the self-assembled layer SAL may be exposed.

According to one or more embodiments, the cover base BS may include one or more selected from the group consisting of aluminum oxide (AlₓO_{y}), silicon oxide (SiOₓ), silicon nitride (SiNₓ), silicon oxynitride (SiOₓN_{y}), and titanium oxide (TiOₓ). However, embodiments of the present disclosure are not limited to the examples described herein.

The cover base BS may be a base for forming the self-assembled layer SAL. For example, hydroxyl groups may be formed on one (e.g., a) surface of the cover base BS to appropriately or suitably form the self-assembled layer SAL.

According to one or more embodiments, the cover base BS may be formed by an Atomic Layer Decomposition (ALD) process. In the ALD process, a relatively small amount of hydroxyl groups may be formed on an outer surface of the layer formed by the ALD process. However, according to one or more embodiments, after the cover base BS is formed during an ALD process, an ultraviolet ozone (UVO) treatment process may be performed to form hydroxyl groups. Thus, a plurality of hydroxyl groups may be formed on the outer surface of the cover base BS, and a plurality of self-assembly reactions may occur, so that the dense self-assembled layer SAL may be formed.

The self-assembled layer SAL may be arranged on the cover base BS. The self-assembled layer SAL may include a self-assembly material (A) arranged in combination with the hydroxyl groups formed on the one surface (e.g., the outer surface) of the cover base BS.

For example, in one or more embodiments, the self-assembled layer SAL may be formed by performing a self-assembly process using the self-assembly material (A) after the hydroxyl groups are formed on the one surface of the cover base BS.

The self-assembly material (A) may be arranged such that the light-emitting elements LD may have hydrophobic properties at the outermost edge (e.g., outermost side surface) of the light-emitting elements LD. The self-assembly material (A) may have hydrophobic properties, and the self-assembled layer SAL including the self-assembly material (A) is formed at the outermost edge (e.g., outermost side surface) of the light-emitting elements LD. Therefore, the surface of the light-emitting element LD may be generally hydrophobic.

According to one or more embodiments, the self-assembly material (A) may include a coupling agent to provide hydrophobic properties. For example, the self-assembly material (A) may include an organosilane-based compound (e.g., an organosilane-based coupling agent). For example, in one or more embodiments, the self-assembly material (A) may include hexyltrimethoxysilane (which may be represented by Chemical Formula 1). However, embodiments of the present disclosure are not limited thereto.

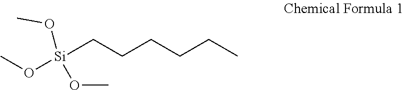

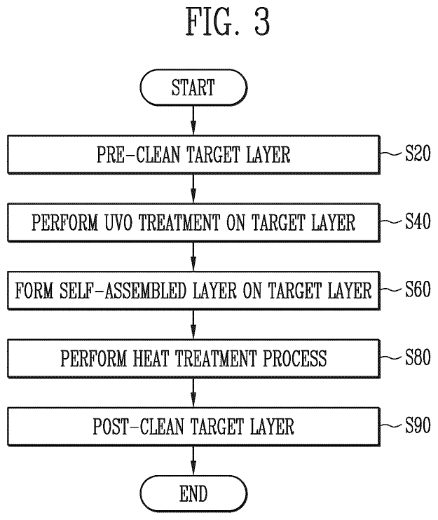

The self-assembled layer SAL may be provided by forming hydroxyl groups on the cover base BS in an appropriate or suitable process environment, followed by a self-assembly process. Accordingly, the light-emitting elements LD may have improved dispersion characteristics, which will be described further with reference to FIG. 3 and the subsequent drawings.

The electrode layer ELL may be arranged on the first semiconductor layer SCL1. The electrode layer ELL may be adjacent to the first end EP1. The electrode layer ELL may be electrically connected to the first semiconductor layer SCL1. A portion of the electrode layer ELL may be exposed. For example, in one or more embodiments, the cover layer CVL may expose a (e.g., one) surface of the electrode layer ELL. The electrode layer ELL may be exposed in a region corresponding to the first end EP1. According to one or more embodiments, a side surface of the electrode layer ELL may be exposed. For example, when the cover layer CVL covers a portion of the semiconductor layer SL, the cover layer CVL may not cover at least a portion of the side surface of the electrode layer ELL. Thus, the cover layer CVL may be suitable for electrical connections to other configurations of the electrode layer ELL adjacent to the first end EP1. According to one or more embodiments, the cover layer CVL may expose not only the side surface of the electrode layer ELL, but also a portion of the side surface of the first semiconductor layer SCL1 and/or the side surface of the second semiconductor layer SCL2.

According to one or more embodiments, the electrode layer ELL may be an ohmic contact electrode. However, embodiments of the present disclosure are not limited to the above example. For example, in one or more embodiments, the electrode layer ELL may be a Schottky contact electrode.

According to one or more embodiments, the electrode layer ELL may include one or more selected from the group consisting of chromium (Cr), titanium (Ti), aluminum (Al), gold (Au), nickel (Ni), oxides thereof, and alloys thereof. However, embodiments of the present disclosure are not limited to the foregoing examples. According to one or more embodiments, the electrode layer ELL may be substantially transparent. For example, in one or more embodiments, the electrode layer ELL may include Indium Tin Oxide (ITO). Accordingly, the electrode layer ELL may be to transmit the emitted light.

The structure and shape of the light-emitting element LD are not limited to the examples described above, and the light-emitting element LD may have one or more suitable structures and shapes according to one or more embodiments. For example, in one or more embodiments, the light-emitting element LD may further include an additional electrode layer which is arranged on a (e.g., one) surface of the second semiconductor layer SCL2 and is adjacent to the second end EP2.

### 2. Method for Surface Treatment of Light-Emitting Element

Hereinafter, with reference to FIGS. 3 to 5, a surface treatment process for the light-emitting element LD according to one or more embodiments will be described. For convenience of explanation, redundant descriptions of previously disclosed content will not be provided or simplified.

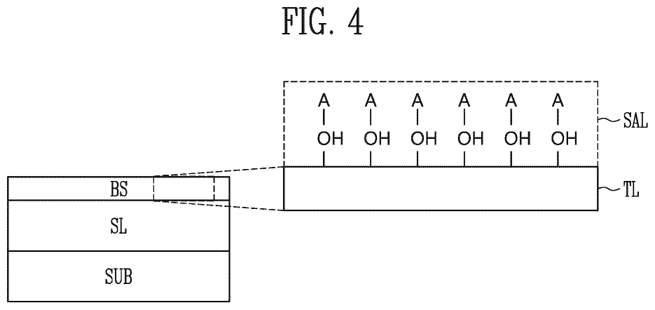

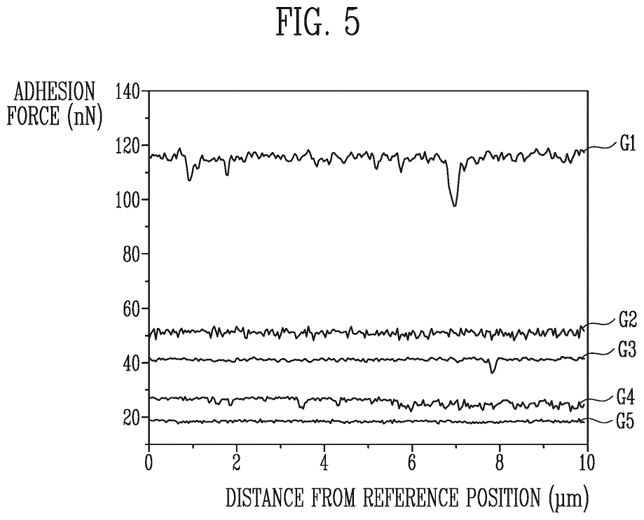

FIG. 3 is a flowchart illustrating a method for surface treatment of a light-emitting element according to one or more embodiments of the present disclosure. FIG. 4 is a schematic cross-sectional view illustrating some of manufacturing processes of a method for surface treatment of a light-emitting element according to one or more embodiments. FIG. 5 is a graph showing adhesion force test results for manufactured examples of the present disclosure.

According to one or more embodiments, a surface treatment process for forming the cover layer CVL of the light-emitting element LD may be provided. For convenience of description, an object on which the surface treatment process is performed (e.g., applied) is defined as a target layer TL.

According to one or more embodiments, the target layer TL may also be referred to as a wafer subject to a surface treatment process.

The cover base BS of the light-emitting elements LD may be the target layer TL in a surface treatment process. For example, a surface treatment process according to one or more embodiments may be performed in some of the processes for manufacturing the light-emitting element LD.

For example, the semiconductor layer SL may be formed (e.g., by epitaxial growth) on a substrate SUB (e.g., a sapphire substrate, and/or the like) for manufacturing the light-emitting element LD, and the cover base BS may be formed after or before the semiconductor layer SL is etched. After the cover base BS is formed, the surface treatment process according to one or more embodiments may be performed.

The method for surface treatment according to one or more embodiments may include treating the target layer with ultraviolet ozone (UVO) treatment at step (e.g., act or task) S40 and forming a self-assembled layer on the target layer at step (e.g., act or task) S60. The method for surface treatment according to one or more embodiments may further include pre-cleaning the target layer at step (e.g., act or task) S20, performing a heat treatment process at step (e.g., act or task) S80, and post-cleaning the target layer at step (e.g., act or task) S90.

In step (e.g., act or task) S20 of pre-cleaning the target layer, at least a portion of the impurities on the target layer TL may be removed prior to the UVO treatment.

In step (e.g., act or task) S20, surface contaminants of the target layer TL may be removed, and the target layer TL may be prepared prior to the UVO treatment.

In step (e.g., act or task) S20, in one or more embodiments, the target layer TL may be pre-cleaned by ultrasonic cleaning using (e.g., with) a mixing solution of an organic solvent and water (e.g., a pre-cleaning mixing solution). For example, the target layer TL may be sonicated using (e.g., with) a first mixing solution including ethanol and water and then with a second mixing solution including acetone.

According to one or more embodiments, the target layer TL may be pre-cleaned by flushing with a mixing solution of an organic solvent and water (e.g., a pre-cleaning mixing solution).

In step (e.g., act or task) S20, each of the pre-cleanings with the first and second mixing solutions may be performed for a period from about 8 to about 12 minutes. For example, the target layer TL may be sonicated for about 10 minutes using (e.g., with) a first mixing solution including ethanol and water, and may then be sonicated for about 10 minutes using (e.g., with) a second mixing solution including acetone.

According to one or more embodiments, after the ultrasonic cleaning is performed in step (e.g., act or task) S20, the surface contaminants of the target layer TL may be further removed using deionized water.

As step (e.g., act or task) S20 is performed, external dust, contaminants, and/or the like on the target layer TL may be removed, thereby improving the surface reactivity of the target layer TL in subsequent processes.

During the UVO treatment of the target layer at step (e.g., act or task) S40, UV light may be applied to the target layer TL under an ozone (O₃) environment.

As the UVO treatment process is performed in step (e.g., act or task) S40, the surface of the target layer TL may be more thoroughly cleaned, and a number of highly reactive hydroxyl groups may be formed on the surface of the target layer TL.

In step (e.g., act or task) S40, ozone may be photolyzed by UV light, radicals (·OH) may be formed, and the formed hydroxyl radicals may react with the surface of the target layer TL to form hydroxyl groups. Accordingly, the surface of the target layer TL may be provided with a plurality of highly reactive hydroxyl groups.

In step (e.g., act or task) S40, the UVO process may be performed with water (H₂O) molecules provided around the periphery of the target layer TL. The hydroxyl groups may be generated more efficiently, and the self-assembled layer SAL may be formed more densely and uniformly (e.g., substantially uniformly) in the subsequent process.

For example, in one or more embodiments, when the UVO process is performed on the target layer TL, water may be arranged around the periphery of the target layer TL. In one example, to perform the UVO process on the target layer TL, a quantity of water, determined based on the area of the target layer TL, may be contained in a petri dish, and the UVO process may be performed with the petri dish containing the water arranged around the periphery of the target layer TL.

According to one or more embodiments, an amount of water provided to the periphery of the target layer TL may be in a range from about 1 mL to about 10 mL per unit area (1 cm²) of the target layer TL (e.g., a top surface or outer surface of the target layer TL). For example, in one or more embodiments, the amount of water provided to the periphery of the target layer TL may be about 2 mL per unit area (1 cm²) of the target layer TL.

In step (e.g., act or task) S40, the ozone may further clean the outer surface of the target layer TL. For example, ozone may break down surface contaminants (e.g., carbon or nitrogen-based contaminants) on the target layer TL. For example, surface contaminants may be broken down and removed by UV light and ozone in the form of H₂O, NOₓ, CO₂, and/or the like.

In step (e.g., act or task) S40, the applied UV light may have a wavelength of 184 nm to 324 nm. For example, in one or more embodiments, the applied UV light may have a wavelength of about 254 nm. When the applied UV light has a wavelength in the numerical range described above, the photolysis of ozone and cleaning of the target layer TL may be performed more thoroughly.

In step (e.g., act or task) S40, the UVO treatment process may be carried out in a room temperature environment. For example, the UVO treatment process may be carried out at a temperature between about 20° C. and about 40° C. In one or more embodiments, the UVO treatment process may be carried out at a temperature of about 23° C. to about 27° C. In one or more embodiments, the UVO treatment process may be carried out in an environment of about 25° C.

In step (e.g., act or task) S40, the UVO treatment process may continue for a period of time sufficient to allow for adequate removal of contaminants and formation of hydroxyl groups. For example, in one or more embodiments, the UVO treatment process may last from about 50 minutes to about 70 minutes. The UVO treatment process may last from about 55 minutes to about 65 minutes. In one or more embodiments, the UVO treatment process may be performed for about 60 minutes. If (e.g., when) the UVO treatment process is performed for less than the time described above, it may be difficult to form sufficient hydroxyl groups, and if (e.g., when) it is performed for more than the time described above, the hydroxyl groups may be saturated and unnecessary power may be desired or required.

In step (e.g., act or task) S60 of forming the self-assembled layer SAL on the target layer, the self-assembled layer SAL having hydrophobic properties may be formed. Accordingly, if (e.g., when) the target layer TL is the cover base BS, the outer surface of the light-emitting element LD may have hydrophobic characteristics as the process of forming the self-assembled layer is performed at step (e.g., act or task) S60.

In step (e.g., act or task) S60, the target layer TL may be immersed in a mixed solution including the self-assembly material (A). For example, in one or more embodiments, a dipping process may be performed on the target layer TL using the mixed solution including the self-assembly material (A). When the target layer TL is immersed in the mixed solution, the hydroxyl groups on the target layer TL may be combined with the self-assembly material (A), and the self-assembled layer SAL may be formed in which the self-assembly material (A) forms a monolayer on the target layer TL. For example, molecules of the self-assembly material (A) may be adsorbed (e.g., physically adsorbed) on the surface on which the hydroxyl group is formed, and/or may form a bond (e.g., a chemical bond) with the hydroxyl group through hydrolysis and polymerization to form a self-assembly (e.g., forming —O-A moieties).

According to one or more embodiments, the mixed solution for carrying out the self-assembly process may include the self-assembly material (A) (e.g., hexyltrimethoxysilane), as described above, and may further include an organic solvent. According to one or more embodiments, the organic solvent may be ethanol, but embodiments of the present disclosure are not limited thereto. For example, the organic solvent may be one or more selected from among dodecane, acetone, methanol, isopropyl alcohol, tetrahydrofuran (THF: Tetrahydrofuran), N-Methyl-2-pyrrolidone (NMP), and propylene glycol methyl ether acetate (PGMEA).

According to one or more embodiments, the self-assembly material (A) may be contained at a concentration of about 50 millimolar (mM) to about 100 millimolar (mM) in a mixed solution for carrying out the self-assembly process. For example, in one or more embodiments, the self-assembly material (A) may be contained at a concentration of about 50 mM in a mixed solution for carrying out the self-assembly process. When the concentration of the self-assembly material (A) satisfies the numerical ranges above, the manufactured light-emitting elements LD may have a sufficiently low sedimentation rate, which may improve the efficiency of the inkjet process for providing the light-emitting elements LD on the base layer BSL.

In step (e.g., act or task) S60, instruments including glass materials may not be used, and instruments used throughout step (e.g., act or task) S60, including the dipping process, may include plastic materials. For example, a container receiving the mixed solution used in the dipping process may include a plastic material.

In step (e.g., act or task) S60, the temperature of the mixed solution when the self-assembly process is performed may be in a range from about 50° C. to about 70° C. According to one or more embodiments, the temperature of the mixed solution may be in a range from about 55° C. to about 65° C. when the self-assembly process is performed. According to one or more embodiments, the temperature of the mixed solution may be about 60° C. when the self-assembly process is performed.

In step (e.g., act or task) S60, the self-assembly process may proceed for as long as it takes for the self-assembled layer SAL to be sufficiently formed. For example, in one or more embodiments, the self-assembly process (e.g., the dipping process) may be performed for a period from about 17 hours to about 48 hours. In one or more embodiments, the self-assembly process may last for about 24 hours.

In step (e.g., act or task) S80 of performing a heat treatment process, heat may be applied to the target layer TL and the self-assembled layer SAL, residual moisture and residual material may be removed, and bonding to the self-assembled layer SAL may be stabilized.

In step (e.g., act or task) S80, a bake process may be performed. The bake process may be performed under a relatively high temperature environment. In one or more embodiments, the bake process may be carried out at a temperature range of about 100° C. to about 140° C. for 0.5 hours to 1.5 hours. In one or more embodiments, the bake process may be carried out at a temperature range of about 60° C. to about 150° C. for 0.5 hours to 2 hours. In one or more embodiments, the bake process may be carried out at about 120° C. for 1 hour.

In step (e.g., act or task) S90 of post-cleaning the target layer, substances and impurities remaining after the heat treatment process may be further removed.

In step (e.g., act or task) S90, after the self-assembled layer SAL is formed, the remaining self-assembly material (A) (e.g., unreacted self-assembly material (A)) may be removed by ultrasonic cleaning with a solvent (e.g., an organic solvent) for about 10 minutes to remove the remaining self-assembly material (A), may be washed again with a solvent, and may be dried using nitrogen gas and/or the like. Accordingly, the structure in which the self-assembled layer SAL is provided on the target layer TL (i.e., the cover base BS) according to one or more embodiments may be provided.

### 3. Experimental Examples on Method for Surface Treatment

As described above, a method for surface treatment according to one or more embodiments is provided and may be applied to the light-emitting element LD according to one or more embodiments. The outer surfaces of the light-emitting elements LD may have improved hydrophobic properties and improved dispersion properties accordingly.

In this regard, the present disclosure will be further illustrated by referring to one or more examples. However, the following examples are provided to further illustrate the present disclosure and are not intended to limit the disclosure of embodiments manufactured according to the following manufacturing examples. For convenience of explanation, redundant descriptions of previously described content will not be provided or simplified.

### (1) Measurement of Surface Contaminants

When the method for surface treatment according to one or more embodiments was applied to the target layer TL, experiments and evaluations were conducted to confirm the effectiveness of surface contaminant removal and the proper formation of hydroxyl groups on the target layer TL.

The UVO treatment process was performed on three different target layers TL with different UVO treatment process conditions respectively applied to some of the target layers TL, while UVO treatment was not performed for the remaining the target layers TL, and all other conditions remained the same. The manufacturing method for each example is described below.

### Experimental Example 1-1

After the target layer TL containing aluminum oxide was prepared, pre-cleaning was performed by flushing with a mixing solution of an organic solvent and water. A petri dish provided with 2 mL of water per unit area (1 cm²) of the target layer TL was placed around the pre-cleaned target layer TL, and was irradiated with UV light at a wavelength of 365 nm for 60 minutes in an ozone environment. In this manner, the UVO-treated target layer TL was prepared.

### Experimental Example 1-2

The UVO-treated target layer TL was prepared by performing the process on the target layer TL in substantially the same manner as in Experimental Example 1-1, except that the UVO treatment process was performed without providing water.

### Experimental Example 1-3

The process for the target layer TL was performed in substantially the same manner as in Experimental Example 1-1, except that the UVO treatment process was not performed, so that the untreated target layer TL was prepared.

The target layers TL prepared according to Experimental Example 1-1, Experimental Example 1-2, and Experimental Example 1-3 were each subjected to X-ray Photoelectron Spectroscopy (XPS) analysis to determine whether any surface contaminants remained on the target layers TL. The atomic percentages of detected elements are listed in Table 1.

TABLE 1

| — | | | | | | | |
|---|---|---|---|---|---|---|---|
| | UVO | Atomic Percentage (atomic %) | | | | | |
| Classification | Conditions | C1s | AI2p | O1s | Ca2p | Na1s | F1s |
| Experimental | 60 minutes, | 4.04 | 33.20 | 56.53 | 0.14 | 3.57 | 2.51 |
| Example | water | | | | | | |
| 1-1 | | | | | | | |
| Experimental | 60 minutes | 4.22 | 33.10 | 55.35 | 0.28 | 3.97 | 3.11 |
| Example | | | | | | | |
| 1-2 | | | | | | | |
| Experimental | — | 11.05 | 33.20 | 55.01 | — | — | — |
| Example | | | | | | | |
| 1-3 | | | | | | | |

Experimentally, it may be determined through X-ray Photoelectron Spectroscopy (XPS) analysis that the surface contamination decreases as smaller amounts of carbon and/or oxygen are detected. Referring to Table 1, it is seen that the surface contamination was reduced when the target layer TL was subjected to the UVO treatment process for 60 minutes and water was additionally used.

### (2) Measurement of Water Contact Angle

When the method for surface treatment according to one or more embodiments was applied to the target layer TL, an experiment was performed to determine the proper formation of hydroxyl groups on the target layer TL according to the time of the UVO treatment process.

The UVO treatment process was performed for each target layer TL by varying the irradiation time of UV light during the UVO treatment process.

### Experimental Example 2-1

After the target layer TL containing aluminum oxide was prepared, pre-cleaning was performed by flushing with a mixing solution of an organic solvent and water. A petri dish provided with 2 mL of water per unit area of the target layer (1 cm²) was placed around the pre-cleaned target layer TL, and was irradiated with UV light at a wavelength of 365 nm for 60 minutes in an ozone environment. In this manner, the UVO-treated target layer TL was prepared.

### Experimental Example 2-2

The UVO-treated target layer TL was prepared by performing the process on the target layer TL in substantially the same manner as in Experimental Example 2-1, except that the target layer TL was irradiated with UV light for 30 minutes.

### Experimental Example 2-3

The UVO-treated target layer TL was prepared by performing the process for the target layer TL in substantially the same manner as in Experimental Example 2-1, except that the target layer TL was irradiated with UV light for 10 minutes.

### Experimental Example 2-4

The process for the target layer TL was performed in substantially the same manner as in Experimental Example 2-1, except that the UVO treatment process was not performed, so that untreated target layer TL was prepared.

The contact angle of water droplet was measured using a goniometer on each of the target layers TL prepared according to Experimental Example 2-1, Experimental Example 2-2, Experimental Example 2-3, and Experimental Example 2-4. The measured contact angles are listed in Table 2.

TABLE 2

| Classification | UVO Conditions | Contact angle |
|---|---|---|
| Experimental Example 2-1 | 60 minutes | 31° |
| Experimental Example 2-2 | 30 minutes | 42° |
| Experimental Example 2-3 | 10 minutes | 50° |
| Experimental Example 2-4 | — | 63° |

Experimentally, it may be determined that the hydrophilicity of the surface of the target layer TL increases as the water contact angle decreases. Referring to Table 2, it is seen that the water contact angle tended to decrease as the UV irradiation time increased. In particular, when UV light was irradiated for 60 minutes, sufficient hydroxyl groups were formed on the TL surface.

### (3) Solvent-Dependent Effects of Self-Assembly Process

When the method for surface treatment according to one or more embodiments was applied to the target layer TL, experiments and evaluations were conducted to determine the extent to which the self-assembly process proceeded depending on a solvent used in the self-assembly process.

While the UVO treatment process conditions and the self-assembly process conditions were generally kept the same, the surface treatment process was performed for three different target layers (the target layers TL) by changing only the type (kind) of solvent used during the self-assembly process. The manufacturing method of each example is described below.

### Experimental Example 3-1

After the target layer TL containing aluminum oxide was prepared, pre-cleaning was performed by flushing with a mixing solution of an organic solvent and water. A petri dish with 2 mL of water per unit area of the target layer (1 cm²) was placed around the pre-cleaned target layer TL, and UV light at a wavelength of 365 nm was irradiated in an ozone environment for 60 minutes. The UVO-treated target layers TL were then immersed in a mixing solution of ethanol and hexyltrimethoxysilane for 24 hours to initiate the self-assembly process. As a result, the self-assembled layer SAL was formed on the surface of the target layer TL, and a sample according to Experimental Example 3-1 was provided.

### Experimental Example 3-2

The process was carried out in substantially the same manner as in Experimental Example 3-1, except that dodecane was used as a solvent for the mixing solution for the self-assembly process, so that a sample according to Experimental Example 3-2 was provided.

### Experimental Example 3-3

The process was carried out in substantially the same manner as in Experimental Example 3-1, except that tetrahydrofuran (THF) was used as a solvent for the mixing solution for the self-assembly process, so that a sample according to Experimental Example 3-3 was provided.

For each of the samples prepared according to Experimental Example 3-1, Experimental Example 3-2, and Experimental Example 3-3, the contact angle of water droplet was measured using a goniometer, and substances present in the samples were analyzed by X-ray Photoelectron Spectroscopy (XPS) analysis. The atomic percentages of the detected elements are listed in Table 3. In Table 4, C/Al indicates a ratio of the C content (e.g., amount) to the Al content (e.g., amount) based on the measured results, and Si/Al indicates a ratio of the Si content (e.g., amount) to the Al content (e.g., amount) based on the measured results.

TABLE 3

| — | | Atomic Percentage (atomic %) | | | | | | |
|---|---|---|---|---|---|---|---|---|
| Classification | | C1s | AI2p | O1s | Si2p | Ca2p | Na1s | F1s |
| Experi- | Ethanol | 14.19 | 30.25 | 51.49 | 1.52 | 0.43 | 1.08 | 1.05 |
| mental | | | | | | | | |
| Example | | | | | | | | |
| 3-1 | | | | | | | | |
| Experi- | Dodecane | 12.78 | 31.43 | 52.87 | 1.18 | 0.25 | 1.06 | 0.43 |
| mental | | | | | | | | |
| Example | | | | | | | | |
| 3-2 | | | | | | | | |
| Experi- | THF | 16.30 | 29.53 | 49.64 | 0.24 | 0.73 | 1.82 | 2.00 |
| mental | | | | | | | | |
| Example | | | | | | | | |
| 3-3 | | | | | | | | |

TABLE 4

| Classification | | C/Al | Si/Al | Contact angle |
|---|---|---|---|---|
| Experimental | Ethanol | 0.469 | 0.050 | 98° |
| Example 3-1 | | | | |
| Experimental | Dodecane | 0.407 | 0.038 | 91° |
| Example 3-2 | | | | |
| Experimental | THF | 0.552 | 0.008 | 68° |
| Example 3-3 | | | | |

Experimentally, when hexyltrimethoxysilane containing silicon is used as the self-assembly material (A), it may be interpreted that active bonding occurred between the self-assembly material (A) and the hydroxyl groups in the self-assembled layer SAL as a large amount of Si is detected. Referring to Tables 3 and 4, it is seen that the amount of Si detected increased when ethanol was used in the self-assembly process compared to other solvents, which may indicate that the self-assembled layer SAL was more robustly formed during the self-assembly process.

### (4) Concentration-Dependent Effects of Self-Assembly Process

When the method for surface treatment according to one or more embodiments was applied to the target layer TL, experiments and evaluations were conducted to determine the extent to which the self-assembly process proceeded depending on the concentration of the self-assembly material (A) in the mixing solution used for the self-assembly process.

While the UVO treatment process conditions and the self-assembly process conditions were generally kept the same, the surface treatment process was performed for four different target layers (the target layers TL) by changing only the conditions for a mixed solution during the self-assembly process. The manufacturing method of each example is described below.

### Experimental Example 4-1

After the target layer TL containing aluminum oxide was prepared, pre-cleaning was performed by flushing with a mixing solution of an organic solvent and water. A petri dish with 2 mL of water per unit area (1 cm²) of the target layer TL was placed around the pre-cleaned target layer TL, and UV light at a wavelength of 365 nm was irradiated in an ozone environment for 60 minutes. The UVO-treated target layer TL was then immersed in a mixing solution containing ethanol and hexyltrimethoxysilane for 24 hours during the self-assembly process. The concentration of hexyltrimethoxysilane in the mixing solution was prepared at 50 mM. In this manner, the self-assembled layer SAL was formed on the surface of the target layer TL, and a sample according to Experimental Example 4-1 was provided.

### Experimental Example 4-2

The process was carried out in substantially the same manner as in Experimental Example 4-1, except that the concentration of hexyltrimethoxysilane in the mixing solution for the self-assembly process was prepared at 3 mM, so a sample according to Experimental Example 4-2 that was provided.

### Experimental Example 4-3

The process was performed in substantially the same manner as in Experimental Example 4-1, except that the mixing solution for the self-assembly process contained only ethanol, so that a sample according to Experimental Example 4-3 was provided.

### Experimental Example 4-4

The process was performed using the same method as in Experimental Example 4-1, except that no pre-cleaning was performed, so that a sample according to Experimental Example 4-4 was provided.

### Experimental Example 4-5

The process was performed in substantially the same manner as in Experimental Example 4-1, except that no pre-cleaning was performed and no UVO treatment was performed prior to the self-assembly process, so that a sample according to Experimental Example 4-5 was provided.

Root-mean-square roughness (RMS), roughness peak to valley (RPV) adhesion force, and average adhesion force were measured for each of the samples prepared according to Experimental Example 4-1, Experimental Example 4-2, Experimental Example 4-3, Experimental Example 4-4, and Experimental Example 4-5.

More specifically, root-mean-square roughness (RMS roughness), RPV adhesion force, and average adhesion force were measured using Atomic Force Microscopy (AFM) on each of the prepared samples. The RMS roughness, the RPV adhesion force, and the average adhesion force were measured twice for each sample, and average values thereof are listed in Table 5.

TABLE 5

| | | RPV | Average | |
|---|---|---|---|---|
| | Root-mean- | adhesion | adhesion | |
| | square | Force | Force | Standard |
| — | roughness (nm) | (nN) | (nN) | deviation |
| Experimental | 1.068 | 134.78 | 114.4 | 0.71 |
| Example 4-1 | | | | |
| Experimental | 0.9635 | 46.205 | 36.13 | 3.54 |
| Example 4-2 | | | | |
| Experimental | 0.865 | 61.98 | 17.82 | 0.88 |
| Example 4-3 | | | | |
| Experimental | 0.6515 | 62.675 | 49.39 | 2.32 |
| Example 4-4 | | | | |
| Experimental | 1.7975 | 28.865 | 24.94 | 1.04 |
| Example 4-5 | | | | |

Furthermore, to clearly analyze the difference in adhesion force for the samples prepared according to Experimental Examples 4-1, 4-2, 4-3, 4-4, and 4-5, the adhesion force of each sample was measured at different positions. More specifically, after an AFM tip was arranged at a reference position of each sample, the adhesion force of each sample was measured by moving the AFM tip, and the results are shown in FIG. 5. A first graph (G1) represents Experimental Example 4-1, a second graph (G2) represents Experimental Example 4-4, a third graph (G3) represents Experimental Example 4-2, a fourth graph (G4) represents Experimental Example 4-5, and a fifth graph (G5) represents Experimental Example 4-3. Referring to Table 5 and FIG. 5, it is seen that the best roughness and adhesion force properties were obtained when ethanol was used as a solvent in the mixing solution for the self-assembly process and hexyltrimethoxysilane was included as the self-assembly material (A) at a concentration of 50 mM. For example, the self-assembly process may proceed most effectively under these conditions.

### 5. Evaluation of Sedimentation Rate

By performing the method for surface treatment according to one or more embodiments under set or predetermined conditions and applying the method to the cover base BS, which is the target layer TL, experiments and evaluations were conducted to confirm whether the light-emitting element LD having the cover layer CVL including the cover base BS and the self-assembled layer SAL exhibited improved dispersion characteristics and low sedimentation rate.

More specifically, to prepare the respective samples of the examples, the semiconductor layer SL was formed on a sapphire substrate, and aluminum oxide was then deposited thereon to form the cover base BS as the target layer TL. The method for surface treatment according to one or more embodiments was applied to the cover base BS as the target layer TL. The conditions of the surface treatment process for each example are as follows.

### Experimental Example 5-1

After the target layer TL was pre-cleaned using acetone, a petri dish provided with 2 mL of water per unit area (1 cm²) of the target layer TL was placed around the pre-cleaned target layer TL and irradiated with UV light at a wavelength of 365 nm in an ozone environment for 60 minutes. Then, the UVO-treated target layer TL was dipped into a mixing solution containing ethanol and hexyltrimethoxysilane for 24 hours to perform the self-assembly process. The concentration of hexyltrimethoxysilane in the mixing solution was prepared at 50 mM. The dipping process was performed using a plastic container and the mixing solution was kept at a temperature of 60° C. The dipping process for the self-assembly process lasted for 24 hours, was post-treated at 60° C. for 30 minutes, and was further washed with acetone. In this manner, the self-assembled layer SAL was formed on the surface of the target layer TL, and a sample according to Experimental Example 5-1 was provided.

### Experimental Example 5-2

The process was carried out in substantially the same manner as in Experimental Example 5-1, except that the concentration of hexyltrimethoxysilane in the mixing solution for the self-assembly process was prepared at 100 mM, so that a sample according to Experimental Example 5-2 was provided.

### Experimental Example 5-3

The process was performed in substantially the same manner as in Experimental Example 5-1, except that the concentration of hexyltrimethoxysilane in the mixing solution for the self-assembly process was prepared at 25 mM, so that a sample according to Experimental Example 5-3 was prepared.

### Experimental Example 5-4

The process was carried out in substantially the same manner as in Experimental Example 5-1, except that the concentration of hexyltrimethoxysilane in the mixing solution for the self-assembly process was prepared at 5 mM, so that a sample according to Experimental Example 5-4 was provided.

### Experimental Example 5-5

The process was carried out in substantially the same manner as in Experimental Example 5-1, except that the concentration of hexyltrimethoxysilane in the mixing solution for the self-assembly process was prepared at 1.5 mM, so a sample according to Experimental Example 5-5 that was provided.

### Experimental Example 5-6

A sample according to Experimental Example 5-6 was provided by performing the process in substantially the same manner as in Experimental Example 5-1, except that the concentration of hexyltrimethoxysilane in the mixing solution for the self-assembly process was prepared to 1.5 mM and the UVO process was not applied.

### Experimental Example 5-7

A sample according to Experimental Example 5-7 was provided by performing the process in substantially the same manner as in Experimental Example 5-1, except that the concentration of hexyltrimethoxysilane in the mixing solution for the self-assembly process was prepared to 1.5 mM, the UVO process was not applied, and dodecane was used as a solvent.

### Experimental Example 5-8

A sample according to Experimental Example 5-8 was provided in substantially the same manner as in Experimental Example 5-1, except that the concentration of hexyltrimethoxysilane in a mixed solution for the self-assembly process was prepared at 1.5 mM, the UVO process was not applied, dodecane was used as a solvent, glass was used as a material of a container receiving the mixed solution to perform a dipping process, and the dipping process was performed for 2 hours under a room temperature environment.

### Experimental Example 5-9

A sample according to Experimental Example 5-9 was provided in substantially the same manner as in Experimental Example 5-1, except that the concentration of hexyltrimethoxysilane in a mixed solution for a self-assembly process was prepared at 1.5 mM, the UVO process was not applied, dodecane was used as a solvent, glass was used as a material of a container to receive a mixed solution to perform a dipping process, and the dipping process was performed for 24 hours under a room temperature environment.

A sedimentation rate was measured for each of the samples prepared according to Experimental Example 5-1, Experimental Example 5-2, Experimental Example 5-3, Experimental Example 5-4, Experimental Example 5-5, Experimental Example 5-6, Experimental Example 5-7, Experimental Example 5-8, and Experimental Example 5-9, and the results are shown in Table 6. More specifically, an ink containing the inorganic light emitting diodes was placed on each sample using a turbidimeter, and the turbidity of the ink was measured during the sedimentation process of inorganic light emitting diodes to measure the sedimentation rate which was defined for each sample. The inks used in the experiments of the respective samples were identical to each other.

TABLE 6

| | Sedimentation |
|---|---|
| Classification | rate |
| Experimental Example 5-1 | 0.10 mm/hr |
| Experimental Example 5-2 | 0.10 mm/hr |
| Experimental Example 5-3 | 0.12 mm/hr |
| Experimental Example 5-4 | 0.12 mm/hr |
| Experimental Example 5-5 | 0.13 mm/hr |
| Experimental Example 5-6 | 0.14 mm/hr |
| Experimental Example 5-7 | 0.15 mm/hr |
| Experimental Example 5-8 | 0.18 mm/hr |
| Experimental Example 5-9 | 0.16 mm/hr |

According to one or more embodiments, the display device DD (see FIG. 6) may include the light-emitting elements LD provided through an inkjet process using the ink including the light-emitting elements LD and a solvent SLV (see FIG. 9). In order to properly perform the inkjet process on the ink INK (see FIG. 9) so that the light-emitting elements LD may be dispersed without agglomeration and the light-emitting efficiency may be improved, the light-emitting elements LD may be dispersed and separated from each other and a low sedimentation rate may be maintained. Referring to Table 6, it is seen that when hexyltrimethoxysilane, which is the self-assembly material (A), was included in the mixing solution at a concentration of 50 mM or more in Experimental Example 5-1, the sedimentation rate was kept low. For example, when the concentration of hexyltrimethoxysilane in the mixing solution was 50 mM or more, the decrease in the sedimentation rate tended to be saturated. Therefore, according to one or more embodiments, by adjusting the concentration of hexyltrimethoxysilane in the mixing solution to 50 mM or more during the self-assembly process, the light-emitting element LD in the ink INK has a low sedimentation rate characteristic, and as a result, the display device DD according to the embodiment may be provided with improved light-emitting efficiency.

### 4. Display Device Including Light-Emitting Elements

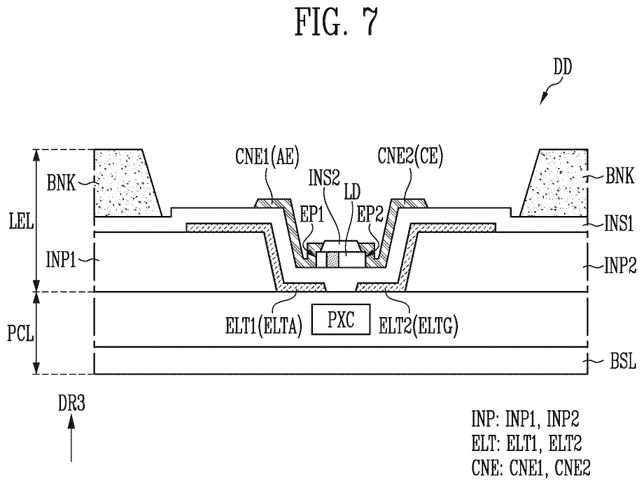

Referring to FIG. 6 and FIG. 7, A display device DD according to one or more embodiments will be described. For convenience of explanation, redundant descriptions of previously described content will not be provided or simplified.

FIG. 6 is a schematic plan view illustrating the display device DD according to one or more embodiments. FIG. 7 is a schematic cross-sectional view illustrating the display device DD according to one or more embodiments.

According to one or more embodiments, the display device DD including the light-emitting element LD which is surface-treated by the method for surface treatment may be provided.

According to one or more embodiments, the display device DD may include a light-emitting structure in which the light-emitting elements LD are formed using an ink INK (see FIG. 9) including the surface-treated light-emitting elements LD.

According to one or more embodiments, the display device DD may include a base layer BSL and pixels PXL formed on the base layer BSL and including the light-emitting elements LD. Although not shown in FIG. 6, in one or more embodiments, the display device DD may further include driving circuitry (e.g., a scan driver and a data driver), wirings, and pads for driving the pixels PXL.

The display device DD (or the base layer BSL) may include a display area DA and a non-display area NDA. The non-display area NDA may refer to an area outside the display area DA. The non-display area NDA may surround at least a portion of the display area DA.

The base layer BSL may form a base surface of the display device DD. The base layer BSL may be a rigid or flexible substrate or film. However, embodiments of the present disclosure are not limited to any particular example.

The display area DA may include an area in which the pixels PXL are arranged (e.g., a pixel area). The non-display area NDA may include an area where no pixels PXL are placed (e.g., dead space). The driving circuitry, the wirings, and the pads connected to the pixels PXL in the display area DA may be arranged in the non-display area NDA.

According to one or more embodiments, the pixel PXL (or a sub-pixel SPX) may include a first sub-pixel SPX1, a second sub-pixel SPX2, and a third sub-pixel SPX3. Each of the first sub-pixel SPX1, the second sub-pixel SPX2, and the third sub-pixel SPX3 may be a sub-pixel. At least one of the first sub-pixel SPX1, the second sub-pixel SPX2, or the third sub-pixel SPX3 may form a pixel unit for emitting one or more suitable colors of light.

The display device DD may include a pixel circuit layer PCL and a light-emitting element layer LEL on the pixel circuit layer PCL.

The pixel circuit layer PCL may include the base layer BSL and a pixel circuit PXC formed on the base layer BSL. Though not shown in FIG. 6, the pixel circuit layer PCL may further include one or more suitable power wirings and/or the like.

The light-emitting element layer LEL may include an insulating pattern layer INP, an alignment electrode layer ELT, a first insulating layer INS1, a bank BNK, the light-emitting element LD, a second insulating layer INS2, and a connection electrode layer CNE.

The insulating pattern layers INP may include first and second insulating patterns INP1 and INP2. The insulating pattern layers INP may be arranged on the pixel circuit layer PCL. The insulating patterned layers INP may protrude in a third direction DR3 and form a step such that the light-emitting elements LD may be properly aligned.

The alignment electrode layer ELT may be arranged on the pixel circuit layer PCL and cover the insulating pattern layer INP. The alignment electrode layer ELT may include a first electrode ELT1 (or a first alignment electrode ELTA) and a second electrode ELT2 (or a second alignment electrode ELTG) spaced and/or apart from each other. According to one or more embodiments, the first electrode ELT1 which is the first alignment electrode ELTA may be an electrode to which an alternating current signal is supplied so as to align the light-emitting elements LD. The first electrode ELT1 may be an electrode to which an anode signal is supplied to cause the light-emitting elements LD to emit light. The second electrode ELT2 which is the second alignment electrode ELTG may be an electrode to which a ground signal is supplied to align the light-emitting elements LD. The second electrode ELT2 may be an electrode to which a cathode signal is supplied to cause the light-emitting elements LD to emit light.

The first electrode ELT1 (or the first alignment electrode ELTA) and the second electrode ELT2 (or the second alignment electrode ELTG) may be supplied (or provided) with a first alignment signal and a second alignment signal, respectively, in a process step (e.g., act or task) in which the light-emitting elements LD are aligned. For example, an ink including the light-emitting elements LD may be supplied (or provided) to an opening, the first alignment signal may be supplied to the first electrode ELT1, and the second alignment signal may be supplied to the second electrode ELT2. The first alignment signal and the second alignment signal may have different waveforms, potentials, and/or phases. For example, in one or more embodiments, the first alignment signal may be an alternating current signal, and the second alignment signal may be a ground signal. However, embodiments of the present disclosure are not limited to the above examples. An electric field may be formed between (or on) the first electrode ELT1 and the second electrode ELT2, and the light-emitting elements LD may be aligned between the first electrode ELT1 and the second electrode ELT2 based on the electric field. For example, the light-emitting elements LD may be moved (or rotated) by a force (e.g., a dielectrophoresis (DEP) force) based on the electric field to be aligned (or arranged) on the first alignment electrode ELTA and the second alignment electrode ELTG.

The first insulating layer INS1 may be arranged on the alignment electrode layer ELT. For example, the first insulating layer INS1 may cover the first electrode ELT1 and the second electrode ELT2.

The bank BNK may be arranged on the first insulating layer INS1. The bank BNK may surround a first region to form an opening. According to one or more embodiments, the ink including the light-emitting element LD may be supplied to the openings defined by the bank BNK, so that the light-emitting element LD may be arranged in the opening.

The light-emitting element LD may be arranged (or aligned) on the alignment electrode layer ELT. According to one or more embodiments, the light-emitting elements LD may be aligned between the first electrode ELT1 and the second electrode ELT2 in a plan view. The light-emitting elements LD may form (or configure) a light-emitting unit.

The light-emitting element LD may be to emit light based on electrical signals provided. For example, the light-emitting element LD may provide light based on a first electrical signal (e.g., an anode signal) provided from a first connection electrode CNE1 and a second electrical signal (e.g., a cathode signal) provided from a second connection electrode CNE2.

The first end EP1 of the light-emitting element LD may be arranged adjacent to the first electrode ELT1, and the second end EP2 of the light-emitting element LD may be arranged adjacent to the second electrode ELT2.

The second insulating layer INS2 may be arranged on the light-emitting element LD. The second insulating layer INS2 may cover the active layer AL of the light-emitting element LD. The second insulating layer INS2 may expose at least a portion of the light-emitting element LD. For example, the second insulating layer INS2 may not cover the first end EP1 and the second end EP2 of the light-emitting element LD, and accordingly, the first end EP1 and the second end EP2 of the light-emitting element LD may be exposed and be electrically connected to the first connection electrode CNE1 and the second connection electrode CNE2, respectively. When the second insulating layer INS2 is formed on the light-emitting element LD after the alignment of the light-emitting element LD is completed, the light-emitting element LD may be prevented from deviating from the aligned position.

The connection electrode layer CNE may be arranged on the first ends EP1 and the second ends EP2 of the light-emitting elements LD. The first connection electrode CNE1 may be arranged on the first ends EP1 so as to be electrically connected to the first ends EP1 of the light-emitting elements LD. The second connection electrode CNE2 may be arranged on the second ends EP2 so as to be electrically connected to the second end EP2 of the light-emitting elements LD.

According to one or more embodiments, the connection electrode layer CNE may include the first connection electrode CNE1 and the second connection electrode CNE2. The first connection electrode CNE1 may be an anode connection electrode AE, and the second connection electrode CNE2 may be a cathode connection electrode CE.

The first connection electrode CNE1 and the second connection electrode CNE2 may be arranged on the first insulating layer INS1. The first connection electrode CNE1 may be electrically connected to the first end EP1 of the light-emitting element LD. The second connection electrode CNE2 may be electrically connected to the second end EP2 of the light-emitting element LD. The first connection electrode CNE1 may be electrically connected to the first electrode ELT1, and the second connection electrode CNE2 may be electrically connected to the second electrode ELT2.

### 5. Method of Manufacturing Display Device

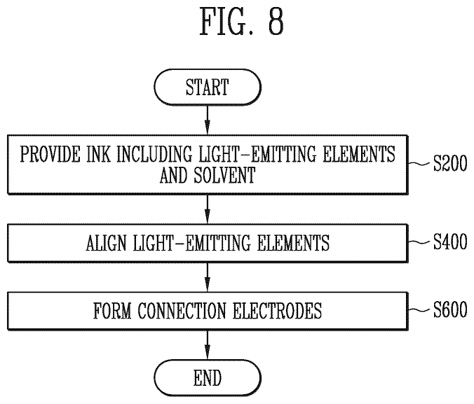

Hereinafter, with reference to FIG. 8 and FIG. 9, a method of manufacturing the display device DD according to one or more embodiments will be described. For convenience of explanation, redundant descriptions of previously described content will not be provided or simplified.

FIG. 8 is a flowchart illustrating a method of manufacturing the display device DD according to one or more embodiments. FIG. 9 is a schematic cross-sectional view illustrating some of manufacturing processes of a method of manufacturing the display device DD according to one or more embodiments.

As described above, the light-emitting element LD which functions as a light source in the display device DD according to one or more embodiments may be included in the ink INK, and may be provided to the display device DD using the ink INK. A method of manufacturing the display device DD according to one or more embodiments will be described in more detail below.

Referring to FIG. 8 and FIG. 9, a method of manufacturing the display device DD according to one or more embodiments may include providing an ink including light-emitting elements LD and a solvent SLV at step (e.g., act or task) S200, aligning the light-emitting elements at step (e.g., act or task) S400, and forming connection electrodes at step (e.g., act or task) S600.

In step (e.g., act or task) S200 of providing the ink including the light-emitting elements and the solvent, the insulating pattern layer INP, the alignment electrode layer ELT, the first insulating layer INS1, and the bank BNK may be arranged on the pixel circuit layer PCL, and the ink INK including the light-emitting elements LD and the solvent SLV may be supplied by a printing device PRI.

The printing device PRI may discharge a fluid, such as the ink INK. The ink INK supplied from the printing device PRI may be provided within an area surrounded by the bank BNK. The solvent SLV may be an organic solvent, and is not limited to any particular example.

According to one or more embodiments, by the surface treatment process, the light-emitting elements LD may have hydrophobic properties on the surface thereof, the light-emitting elements LD may be appropriately or suitably dispersed and separated from each other, and the phenomenon of agglomeration between the light-emitting elements LD may be prevented or reduced. Furthermore, the light-emitting elements LD may have improved sedimentation time characteristics by the surface treatment process according to the embodiments, and thus, the process efficiency of the inkjet printing process may be improved.

In step (e.g., act or task) S400 of aligning the light-emitting elements, an electric field may be formed between the first electrode ELT1 and the second electrode ELT2 such that the light-emitting elements LD may be aligned between the first electrode ELT1 and the second electrode ELT2. Accordingly, the light-emitting elements LD may be arranged (e.g., aligned) such that the first end(s) EP1 of the light-emitting element(s) LD may face the first electrode ELT1 and the second end(s) EP2 of the light-emitting element(s) LD may face the second electrode ELT2.

Referring to FIG. 7, in step (e.g., act or task) S600 of forming the connection electrodes, the solvent SLV may be removed after the previous process (e.g., after the alignment process), and the first and second connection electrodes CNE1 and CNE2 may be patterned. Accordingly, each of the light-emitting elements LD may receive an anode signal and a cathode signal and emit light.

According to one or more embodiments, additional layers, such as additional insulating layers, may be arranged, and the display device DD according to one or more embodiments may be provided.

### 6. Electronic Device Including Display Device

According to one or more embodiments, an electronic device 10 including the display device DD may be provided. For convenience of explanation, redundant descriptions of previously disclosed content will not be provided or simplified.

The display device DD according to one or more embodiments may be applied to one or more suitable electronic devices 10. The electronic device 10 according to one or more embodiments may include the above-described display device DD and further include modules or devices having other additional functions in addition to the display device DD.

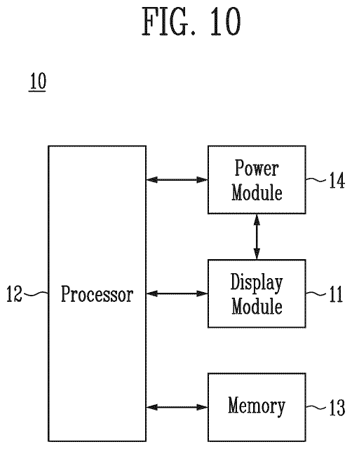

FIG. 10 is a block diagram of the electronic device 10 according to one or more embodiments of the present disclosure. Referring to FIG. 10, the electronic device 10 according to one or more embodiments may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), or a controller.

The memory 13 may store data and/or information used to operate the processor 12 and/or the display module 11. When the processor 12 executes an application stored in the memory 13, image data signals and/or input control signals may be transferred to the display module 11. The display module 11 may process the provided signals and output image information on a display screen.

The power module 14 may include a power supply module, such as a power adapter or a battery device, and a power conversion module. The power conversion module converts power supplied by the power supply module and generates power to operate the electronic device 10.

At least one of the above-described components of the electronic device 10 may be included in the display device DD according to one or more embodiments. In addition, in terms of functionality, some of the individual modules included in one module may be included in the display device DD and others may be provided separately from the display device DD. For example, in one or more embodiments, the display module 11 is included in the display device, whereas the processor 12, the memory 13, and the power module 14 are not included in the display device DD and are instead provided separately in the electronic device 10.

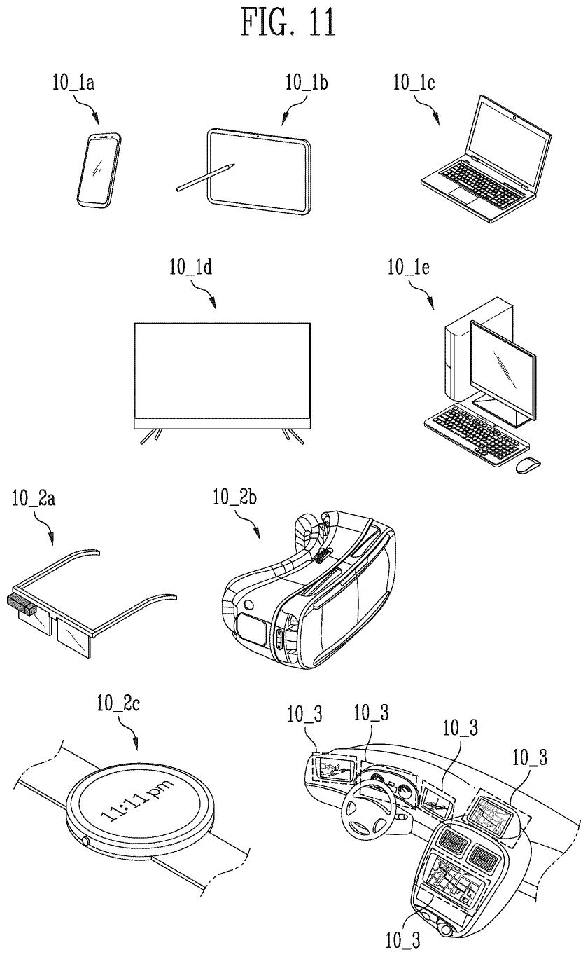

FIG. 11 shows schematic views of various embodiments of an electronic device according to the present disclosure.

Referring to FIG. 11, one or more suitable types (kinds) of electronic devices to which embodiments of the display device DD are applied may include an electronic device to display images such as a smartphone 10_1a, a tablet PC 10_1b, a laptop computer 10_1c, a television (TV) 10_1d, and a desktop monitor 10_1e, a wearable electronic device including a display module such as smart glasses 10_2a, a head-mounted display (HMD) 10_2b, and a smart watch 10_2c, and an automotive electronic device 10_3 including a display module such as a center information display (CID) arranged in the instrument cluster, the center fascia, and the dashboard of a vehicle, and a room mirror display thereof.

According to one or more embodiments of the present disclosure, a method for surface treatment of a light-emitting element, a method of manufacturing a display device including a light-emitting element provided with ink, and an electronic device including the display device, in each of which a plurality of reactive functional groups (e.g., hydroxyl groups) may be formed by appropriately or suitably performing surface treatment of a target layer to thereby form a dense self-assembled layer, may be provided.

According to one or more embodiments of the present disclosure, a method for treating a surface of a light-emitting element, a method of manufacturing a display device including a light-emitting element provided using ink, and an electronic device including the display device, in each of which dispersion characteristics among light-emitting elements by forming a dense self-assembled layer may be improved, thereby efficiently aligning the light-emitting elements, may be provided.

According to one or more embodiments of the present disclosure, a method for treating a surface of a light-emitting element, a method of manufacturing a display device including a light-emitting element provided using ink, and an electronic device including the display device, in each of which contaminants from a target layer may be removed, may be provided.

In the context of the present application and unless otherwise defined, the terms “use,” “using,” and “used” may be considered synonymous with the terms “utilize,” “utilizing,” and “utilized,” respectively.

As used herein, the term “and/or” or “or” may include any and all combinations of one or more of the associated listed items. Expressions such as “at least one of,” “one of,” and “selected from,” when preceding a list of elements, modify the entire list of elements and do not modify the individual elements of the list. For example, “at least one of a, b, or c,” “at least one selected from a, b, and c,” “at least one selected from among a to c,” and/or the like, may indicate only a, only b, only c, both (e.g., simultaneously) a and b, both (e.g., simultaneously) a and c, both (e.g., simultaneously) b and c, all of a, b, and c, or variations thereof. The “/” utilized herein may be interpreted as “and” or as “or” depending on the situation.

As utilized herein, the terms “substantially,” “about,” or similar terms are used as terms of approximation and not as terms of degree, and are intended to account for the inherent deviations in measured or calculated values that would be recognized by those of ordinary skill in the art. “About” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, or 5% of the stated value.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this disclosure, including the claims, to expressly recite any sub-range subsumed within the ranges expressly recited herein.

The display device, the electronic devices/apparatus, the display device-manufacturing apparatus, or any other relevant apparatuses/devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random-access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

Also, it should be understood that, even if the terms “about,” “approximately,” or “substantially” are not expressly recited in a certain given element (e.g., claim element), the scope of such element (e.g., claim element) is intended to include variations that are insubstantial or within the understanding of one of ordinary skill in the art. For example, numerical values and ranges provided herein are intended to include tolerances and measurement uncertainties that would be recognized by those skilled in the art, and the elements (e.g., claim elements) should be construed accordingly to encompass such equivalents.

The embodiments described above are provided to explain the present disclosure, but these embodiments are not intended to limit the scope of the present disclosure. It will be understood by those skilled in the art that one or more suitable changes, substitutions, and alternatives may be made therein without departing from the scope of the disclosure as set forth by the appended claims and their equivalents. Therefore, the technical scope of the present disclosure may be determined based on the scope of the accompanying claims, equivalents thereof, and their functional equivalents.

What is claimed is:

1. A method, comprising:
performing ultraviolet ozone (UVO) treatment on a target layer; and
forming a self-assembled layer on the target layer,
wherein the performing the UVO treatment comprises irradiating the target layer with UV light for 50 minutes to 70 minutes,
wherein the forming the self-assembled layer comprises dipping the target layer into a mixing solution comprising ethanol and a coupling agent at 50° C. to 70° C., and
wherein the method is a method for surface treatment.

2. The method of claim 1, wherein in the forming of the self-assembled layer, the coupling agent is at a concentration of 50 millimolar (mM) to 100 millimolar (mM) in the mixing solution.

3. The method of claim 1, wherein in the forming of the self-assembled layer, a container receiving the mixing solution comprises a plastic material.

4. The method of claim 1, wherein the UV light has a wavelength of 184 nm to 324 nm.

5. The method of claim 1, wherein the performing the UVO treatment is carried out within a temperature of 20° C. to 40° C.

6. The method of claim 1, wherein in the irradiating of the target layer, the UV light is provided while water is arranged around the target layer.

7. The method of claim 6, wherein an amount of the water provided around the target layer is from 1 mL to 10 mL per unit area (1 cm²) of the target layer.

8. The method of claim 1, wherein the coupling agent is hexyltrimethoxysilane.

9. The method of claim 1, wherein the dipping the target layer is performed for a period from 17 hours to 48 hours.

10. The method of claim 1, further comprising pre-cleaning the target layer before performing the UVO treatment,
wherein the pre-cleaning the target layer comprises ultrasonically cleaning the target layer with a pre-cleaning mixing solution comprising ethanol and water.

11. The method of claim 1, further comprising performing a heat treatment process after forming the self-assembled layer,
wherein the performing the heat treatment process comprises performing a bake process at a temperature range of 100° C. to 140° C. for a period of 0.5 hours to 1.5 hours.

12. The method of claim 11, further comprising post-cleaning the target layer after performing the heat treatment process,
wherein the post-cleaning the target layer comprises:
ultrasonically cleaning the target layer with an organic solvent; and
drying the target layer utilizing nitrogen gas.

13. A manufacturing method, the manufacturing method comprising:
providing an ink comprising a light-emitting element and a solvent on a base layer;
aligning the light-emitting element between a first electrode and a second electrode formed on the base layer; and
forming a first connection electrode electrically connected to a first end of the light-emitting element and a second connection electrode electrically connected to a second end of the light-emitting element,
wherein the light-emitting element comprises a semiconductor layer and a cover layer covering at least a portion of the semiconductor layer, and
wherein the cover layer is surface-treated by the method according to claim 1 and comprises a cover base forming the target layer and the self-assembled layer formed on the cover base, and
wherein the manufacture method is a method of manufacturing a display device.

14. An electronic device, comprising:
a processor;
a display device outputting image information based on a signal provided from the processor; and
a power module supplying power to the display device,
wherein the display device is manufactured by a manufacturing method comprising:
providing an ink comprising a light-emitting element and a solvent on a base layer;
aligning the light-emitting element between a first electrode and a second electrode formed on the base layer; and
forming a first connection electrode electrically connected to a first end of the light-emitting element and a second connection electrode electrically connected to a second end of the light-emitting element,
wherein the light-emitting element comprises a semiconductor layer and a cover layer covering at least a portion of the semiconductor layer, and
wherein the cover layer is surface-treated by a surface-treatment method and comprises a cover base forming a target layer and a self-assembled layer formed on the cover base, and
wherein the surface-treatment method comprises:
performing ultraviolet ozone (UVO) treatment on the target layer; and
forming the self-assembled layer on the target layer,
wherein the performing the UVO treatment comprises irradiating the target layer with UV light for 50 minutes to 70 minutes, and
wherein the forming the self-assembled layer comprises dipping the target layer into a mixing solution comprising ethanol and a coupling agent at 50° C. to 70° C.
